(19) United States
(12) Patent Application Publication
(10) Pub. No.: US 2013/0113712 A1
(43) Pub. Date: May 9, 2013

(54) User Interface Panel Connection

(71) Applicant: Vicente Calvo Alonso, Piispanristi (FI)

(72) Inventor: Vicente Calvo Alonso, Piispanristi (FI)

(73) Assignee: Nokia Corporation

(21) Appl. No.: 13/289,268

(22) Filed: Nov. 4, 2011

(51) Int. Cl. G06F 3/041; H01R 43/00; H05K 1/11

(52) U.S. Cl. 345/173; 174/261; 361/748; 29/825

(57) ABSTRACT

An apparatus including a user interface panel having a plurality of substrate layers and a plurality of electrically conductive lines on the substrate layers. The substrate layers form perimeter side edges of the user interface panel. The electrically conductive lines each have an end forming an electrical contact pad at the perimeter side edges. The electrical contact pads are arranged in rows at more than one of the perimeter side edges. Each electrical contact pad is configured to directly connect to a separate contact of a user interface panel receiving socket.

### BACKGROUND

1. Technical Field

The exemplary and non-limiting embodiments relate generally to a user interface panel and, more particularly, to a configuration of a user interface panel connection.

2. Brief Description of Prior Developments

Some user interfaces can include a display panel connected to a driver/controller. A driver/controller can be mounted directly to a non-active area of the panel. Alternatively, a driver/controller can be connected to the panel by a flexible printed circuit (FPC) which has an end directly connected to the non-active area of the panel. In both cases, besides the non-active area needed for the direct connection of the driver/controller or the FPC, additional non-active area is needed to provide paths for conductors from the gate lines and source lines to the driver/controller or the flexible printed circuit. This combined non-active area takes up potentially useful space of the panel and/or prevents the panel from being reduced in size versus the size of the active area of the panel.

### SUMMARY

The following summary is merely intended to be exemplary. The summary is not intended to limit the scope of the claims.

In accordance with one aspect, an apparatus is provided including a user interface panel having a plurality of substrate layers and a plurality of electrically conductive lines on the substrate layers. The substrate layers form perimeter side edges of the user interface panel. The electrically conductive lines each have an end forming an electrical contact pad at the perimeter side edges. The electrical contact pads are arranged in rows at more than one of the perimeter side edges. Each electrical contact pad is configured to directly connect to a separate contact of a panel receiving socket.

In accordance with another aspect, an apparatus is provided comprising a socket comprising electrical contacts; a user interface panel and a display driver. The user interface panel is mounted in the socket. The user interface panel comprises a plurality of electrically conductive lines extending across the user interface panel. Each of the electrically conductive lines comprises an end forming an electrical contact pad. The electrical contact pads are arranged in rows along perimeter edges of the user interface panel. The electrical contacts of the socket directly connect to the electrical contact pads at the perimeter edges. The display driver is connected to the electrical contacts of the socket, and is spaced from the user interface panel.

In accordance with another aspect, a method comprises inserting a user interface panel into a socket, where the user interface panel comprises a plurality of electrically conductive lines extending across the user interface panel, where each of the electrically conductive lines comprises an end forming an electrical contact pad, where the electrical contact pads are arranged in rows along perimeter edges of the user interface panel; and electrically connecting the contact pads directly to electrical contacts of the socket, where the electrical contact pads automatically directly contact the electrical contacts of the socket when the user interface panel is inserted into the socket.

### BRIEF DESCRIPTION OF THE DRAWINGS

The foregoing aspects and other features are explained in the following description, taken in connection with the accompanying drawings, wherein:

FIG. 1 is a front view of an example embodiment;

FIG. 2 is a block diagram illustrating some of the components of the apparatus shown in FIG. 1;

FIG. 3 is a front view of the display shown in FIGS. 1 and 2;

FIG. 4 is an enlarged schematic view illustrating some components of the display shown in FIG. 3;

FIG. 5 is a cross sectional view illustrating some of the components of the display shown in FIGS. 3 and 4;

FIG. 5A shows an example of different heights of shelves and contact pads;

FIG. 5B shows contacts pads on a side with no shelves;

FIG. 6 is a schematic illustration showing the non-active area of the display shown in FIGS. 3-5;

FIG. 7 is a perspective view illustrating connection of the panel shown in FIGS. 3-5 to a printed wiring board by a socket;

FIG. 8 is a diagram illustrating an alternate example embodiment;

FIG. 9 is a diagram illustrating another alternate example embodiment;

FIG. 10 is a diagram illustrating steps of an example method;

FIG. 11 is a top plan view of an example embodiment;

FIG. 12 is a schematic sectional view of the apparatus shown in FIG. 11;

FIG. 13 is a top plan view of another example embodiment;

FIG. 14 is a schematic sectional view of the apparatus shown in FIG. 13;

FIG. 15 is a top plan view of another example embodiment;

FIG. 16 is a schematic sectional view of the apparatus shown in FIG. 15;

FIG. 17 is a schematic sectional view of an alternate embodiment of the apparatus shown in FIG. 15; and

FIG. 18 is a schematic sectional view of an alternate embodiment of the apparatus shown in FIG. 15.

### DETAILED DESCRIPTION OF EMBODIMENTS

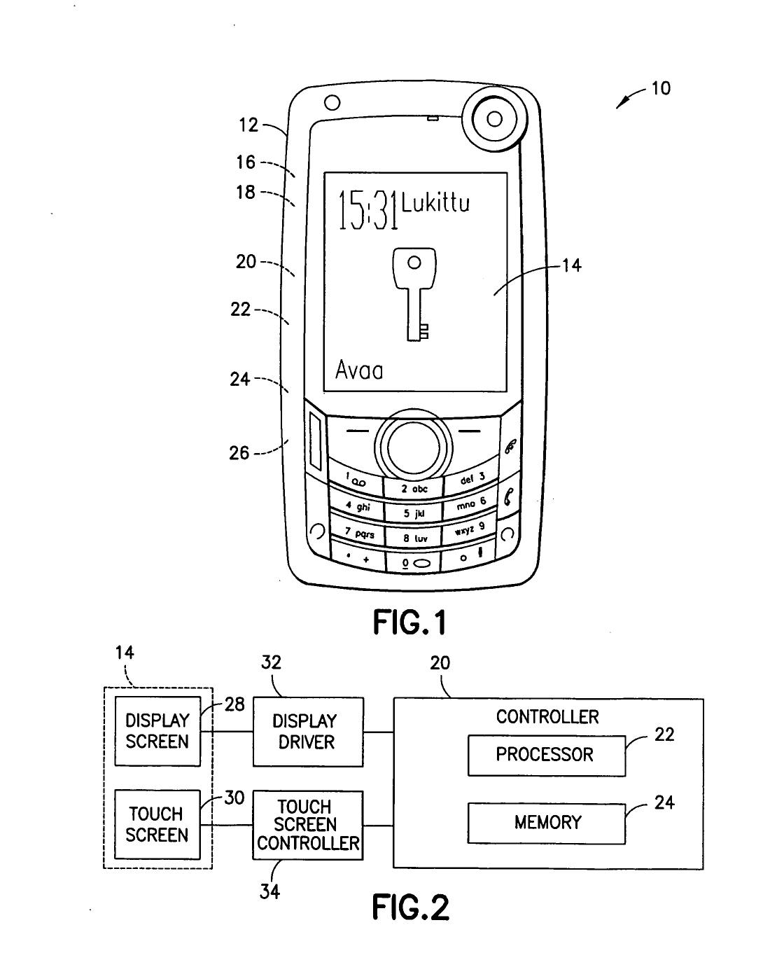

Referring to FIG. 1, there is shown a perspective view of an apparatus 10 incorporating features of an example embodiment. Although the features will be described with reference to the example embodiments shown in the drawings, it should be understood that features can be embodied in many alternate forms of embodiments. In addition, any suitable size, shape or type of elements or materials could be used.

The apparatus 10 in this example is a hand-held portable electronic device which can comprise a telephone application, Internet browser application, camera application, video recorder application, music player and recorder application, email application, navigation application, gaming application, and/or any other suitable electronic device application. The apparatus 10, in this example embodiment, comprises a housing 12, a display 14, a receiver 16, a transmitter 18, a controller 20 which can include (referring also to FIG. 2) at least one processor 22, at least one memory 24, and software, and a rechargeable battery 26. However, all of these features are not necessary to implement the features described below. Thus, for example, features could be used in any suitable type of device, such as a telephone, computer monitor or television.

The display 14 in this example is a touch screen display which functions as both a display screen and as a user input. However, features described herein could be used in a display which does not have a touch, user input feature. Alternatively, features could be used in a touch panel located over a conventional display screen. As schematically illustrated in FIG. 2, the display 14 has a display screen section 28 and a touch screen section 30. The display screen section 28 is connected to a display driver 32. The touch screen section 30 is connected to a touch screen controller 34. The driver 32 and controller 34 are connected to the controller 20.

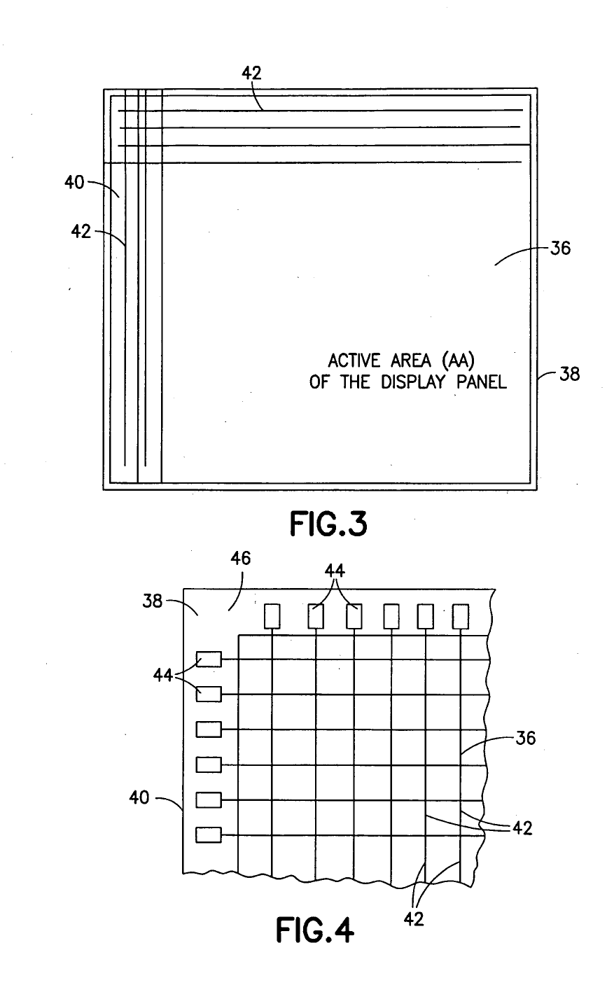

Referring also to FIG. 3, the display 14 includes an active area 36 and a non-active area 38. The active display area 36 is configured to display information and receive user input. The non-active area is not able to display information or receive user input. The non-active area is nonetheless necessary for locating certain functional aspects of the display 14 for the display to function properly. The display 14 comprises at least one substrate 40 and electrical conductors or lines 42 inside the substrate 40 (only some of which are shown in FIG. 3). The lines 42 are orientated in a general grid pattern at different layers in the substrate 40. In this example embodiment the lines 42 comprise source lines and gate lines which form the display screen section 28, and readout lines and gate lines which form the touch screen section 30.

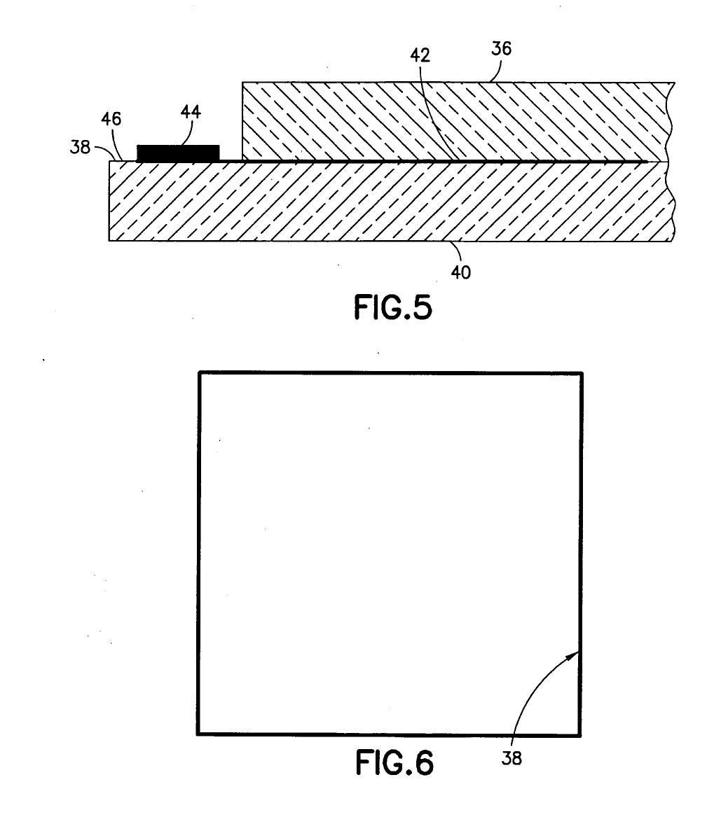

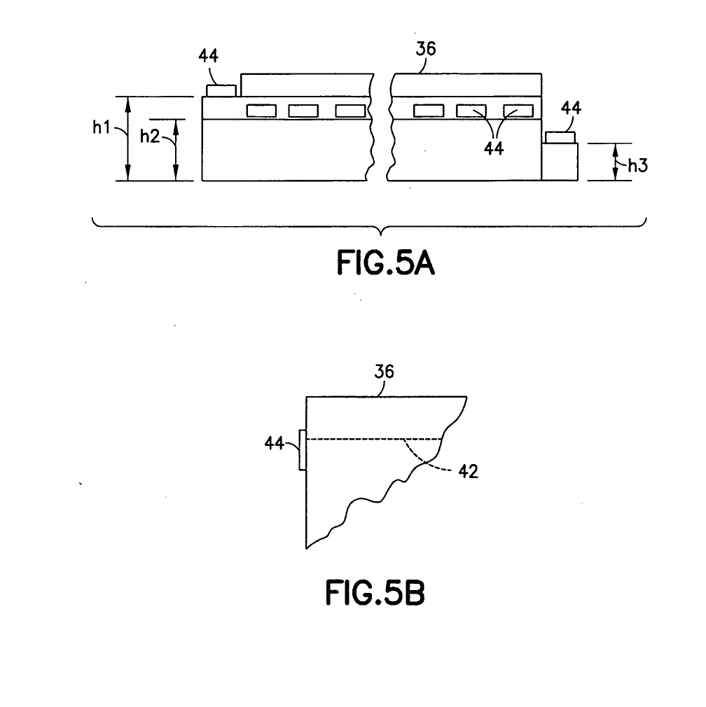

Referring also to FIG. 4, the lines 42 extend out from the active area 36 to the non-active area 38 where they each end at a contact pad 44. Referring also to FIG. 5, in this example embodiment the substrate 40 has at least one shelf or ledge 46 at its sides. The contact pads 44 are located on a top side of this shelf 46. In one type of example, different height shelves could be provided at different sides; such as formed by different substrate layers. For example, a first substrate could be a bottom substrate layer, a second substrate could be a top substrate layer, and a third substrate could be an intermediate substrate layer. In this example, a first set of conductor lines could be provided on the top surface of the bottom substrate layer and a second set of the conductor lines could be provided on the top surface of the intermediate substrate layer. Thus, a first set of conductor lines (between the first and intermediate layers) could establish their respective contacts pads 44 at a first height (generally at the height of the top surface of the bottom substrate layer), and the second set of conductor lines (between the intermediate layer and the top layer) could establish their respective contacts pads 44 at a second different height (generally at the height of the top surface of the intermediate substrate layer). In other words, the height of the shelf 46 at each side could be different to accommodate the different heights of the lines 42 in the substrate 40; such that no bend of the lines 42 is needed. Thus, the lines 42 can be provided as completely straight, and each in a single plane between its ends (one end being the pad 44). An example of this is shown in FIG. 5A with three shelves 46a, 46b, 46c shown at different heights h1, h2, h3. Referring also to FIG. 6, only the non-working area 38 is shown. The non-working area 38 is merely a small perimeter section of the display; perhaps just enough room or area to locate the pads 44. The non-active area 38 is not large enough to connect the driver 32 or controller 34 or a flexible printed circuit (FPC). FIG. 5B shows an alternate embodiment where the pads are formed on the lateral sides of the substrate rather than a shelf.

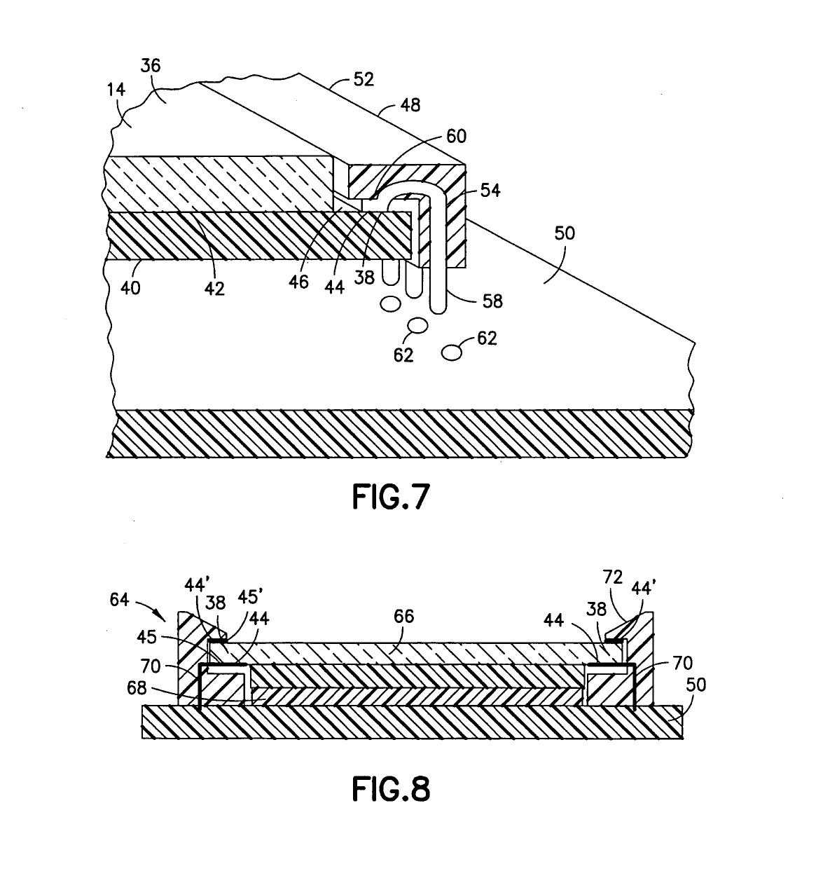

Referring also to FIG. 7, the electrical connection of the display 14 to other components of the apparatus 10 comprises a socket electrical connector 48. The electrical connector 48 functions as a user interface panel receiving socket to both electrically and mechanically attached the display 14 to a printed wiring board (PWB) 50. The socket can also function as a mechanical holder for the optical elements such as optical foils, lightguide, reflectors, etc. for an LCD display. The socket comprises a frame or housing 52 and electrical contacts 54. In this example the frame 52 is comprises of molder plastic or polymer material with a center receiving area which receives the display 14. The frame 52 has an overhang ledge 46. The contacts each have a first end 58 and a second end 60. The first ends are through-hole mounting posts configured to be mounted in holes 62 of the PWB 50. However, in alternate embodiments any suitable connection could be provided including a surface mount solder tail, or solder ball connection, or a non-soldered connection for example. The second ends 60 comprise spring contact sections which are configured to press against the top side of the contact pads 44. In an alternate embodiment the second ends 60 could be soldered to the top sides of the contact pads 44, such as by reflow solder for example.

With the socket 48 attached to the PWB 50, the display 14 is mechanically and electrically attached by the socket 48 to the PWB 50. The display driver 32 and touch screen controller 34 can be provided on the PWB 50. Thus, the PWB 50 and the socket 48 can attach the display 14 to the display driver 32 and touch screen controller 34. The PWB 50 could be a conventional PWB having other components of the apparatus 10, but with the new addition of the display driver 32 and touch screen controller 34 thereon. By not having the display driver 32 and/or touch screen controller 34 on the display 14, and by not having a FPC attached to the display 14 with the display driver 32 and/or touch screen controller 34 on the FPC, and by not having the gate lines running through the edges towards a common edge, the size of the non-active area 38 can be much smaller than a conventional display, such as a Chip-On-Glass (COG) or Chip-On-Foil (COF) configuration.

Features of the example embodiment described above allows for a reduction in relative size of the non-active/active area on a display/touch panel, on a display/touch assembly with a PWB, and perhaps as a display/touch assembly on an A-Cover. Functional areas of the User Interface (UI, e.g. a visible area (Active Area) of the display panel, and/or an input area of the touch panel etc.) of the mobile device (or TV-set, etc.) can be maximized, and non-functional (non-active(display)/non-input(touch)) areas can be minimized by not using current Chip-On-Glass (COG) and Chip-On-Foil (COF) solutions. Current Chip-On-Glass (COG) and Chip-On-Foil (COF) solutions use non-active area of the display, touch and display/touch panels for:
Gate lines (COF and COG), display and touch
Source lines (COF), display
Readout lines (COF and COG), touch
Flex Foil assembly on the Glass (COF and COG)
Display driver or/and touch controller IC (COG)

Example embodiments comprising features described herein may comprise a display panel, touch panel or display/touch panel which does not include a place for attaching a Flex foil (FCP), display driver IC, touch controller IC, display driver/touch controller IC and source/gate lines along display panel or readout/gate lines along touch panel edges. This makes it possible to minimize the non-active (display) and/or non-input (touch) area on panels. Source/gate/readout lines can be routed to edges of the panel directly (the size of the non-active area merely being equal to or slightly greater than the electrical connection pads on the edges of the panel); not lengthwise along edges of the panel.

An assembly order may comprise:
The socket is assembled on a baseband, which is connected to other electrical devices (e.g. engine)
The display or touch or display/touch panel is assembled into a socket which includes needed electrical connections (such as an inner part of it) for source/gate (display) and/or readout/gate (touch).

It should also be understood that the socket can be a part of an A-cover (a front cover) of the mobile device or TV-set. The display panel, touch panel or display/touch panel can be assembled into the socket which also may give a fastening and mechanical support to the panel as well as needed electrical connections between these two components.

A display/touch panel can be made so that route/source/readout gates are routed towards the edge of the glass. A different part, a socket, contains all the electrical connectors that will connect the panel to the device printed circuit board. The display/touch panel driver IC and also the electrical components can then be located somewhere else in the PWB. The socket could also be made so that it has a double function, like a device cover part, such as an A-cover for example. An extra part (cushion, etc) could be added to ensure the electrical interconnection.

Advantages include a non-active area which is minimized specially in the edge where the driver IC and FPC is in the traditional constructions. It gives possibilities to decrease device sizes for a fixed display size. It gives freedom regarding the location of the driver IC and rest of electrical components. Display panel can be assembled onto the connector, which retains the display by some clips. Display can be supported by a cushion underneath, and the spring force of the connector clips, ensuring the good contact between pads.

Referring also to FIG. 8, an alternate example embodiment is shown. This example comprises the PWB 50, a socket 64, a panel 66 and a cushion 68. The socket 64 comprises electrical contacts 70 and retaining clips 72. The panel 66 has lines with contact pads 44 facing downward on the non-active area 38. The cushion 68 is located between the bottom of the panel 66 and the top side of the PWB 50. The clips 72 and cushion 68 act together to bias the pads 44 against the top sides of the contacts 70.

In addition to the contact pads 44 facing downward on the non-active area 38, the substrate assembly could comprise contact pads 44′ facing upward on the non-active area 38. Thus, the substrate layer(s) form a first shelf 45 having a first height and a second shelf 45′ having a second height, where a first row of the electrical contact pads are on the first shelf at the first height, and where a second row of the electrical contact pads are on the second shelf at the second height. In this example the bottom surface of the retaining clip 72 may include contacts to contact the pads 44′. Thus, it is possible to have pads at both top and bottom sides of the substrate(s) at different heights.

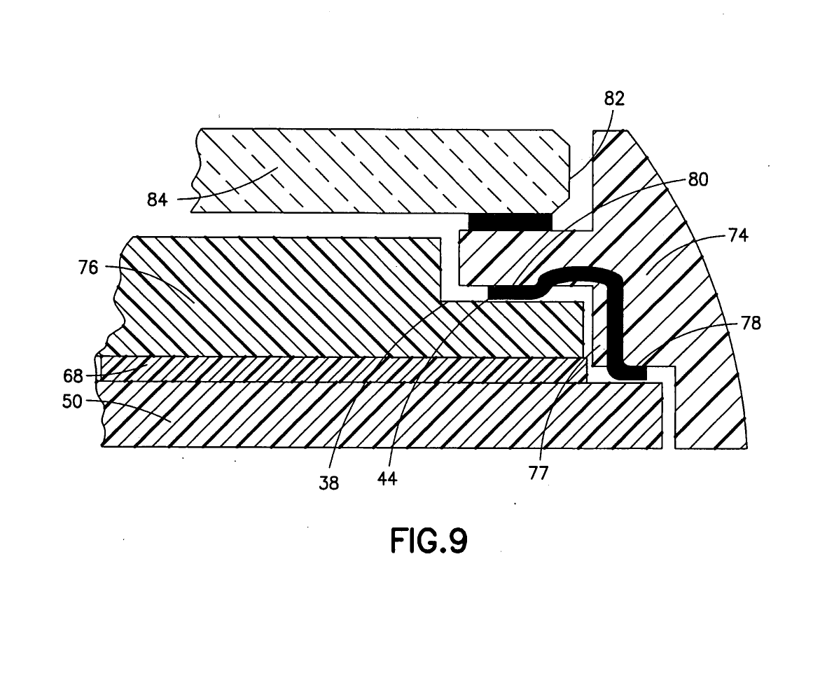

Referring also to FIG. 9, another alternate example embodiment is shown. This example comprises the PWB 50, a socket 74, a panel 76 and a cushion 68. The socket 74 comprises electrical contacts 77. The panel 76 has lines with contact pads 44 facing upward on the non-active area 38. The cushion 68 is located between the bottom of the panel 76 and the top side of the PWB 50. The contacts 77 have a first end 78 attached to the PWB 50 and a second end 80 located against the top side of the pad 44. The socket 74 is part of a housing of the apparatus, such as an A-cover for example. In this example the housing 74 has a seat 82 which has a front window 84 attached in the seat 82 to protect the panel 76.

Referring also to FIGS. 11-12, the socket 100 could be a connector such as 48 shown in FIG. 7 or a 64 in FIG. 8, or an housing member such as 74 shown in FIG. 9 with the electrical contacts on the housing member. The user interface panel 102 could be, for example, a touch panel (with no electronic display feature), or a display panel (with no touch feature), or an integrated display/touch panel having both an electronic display feature and a touch feature (i.e., a touch screen).

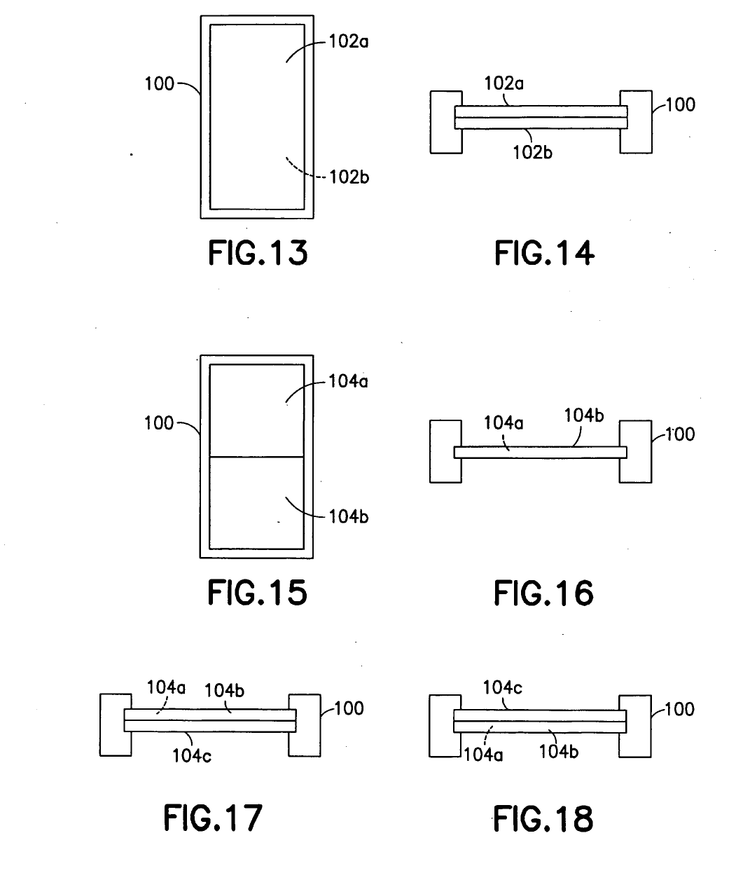

Referring also to FIGS. 13-14, the apparatus could comprise the socket 100 and two of the user interface panels 102a, 102b. The user interface panels 102a, 102b are located one above the other is a general stacked configuration. For example, in one embodiment 102a could be a display panel and 102b could be a touch panel. In another example embodiment 102a could be a touch panel and 102b could be a display panel. In another example embodiment 102a could be a touch panel and 102b could be an integrated display/touch panel. In another example embodiment 102a could be an integrated display/touch panel and 102b could be a touch panel. In another example embodiment 102a could be an integrated display/touch panel and 102b could be a display panel. In another example embodiment 102a could be a display panel and 102b could be an integrated display/touch panel.

Referring also to FIGS. 15-16, in another example embodiment the apparatus could comprise a socket 100 and two user interface panels 104a, 104b located next to each other. In one type of example, 104a could be a display panel and 104b could be touch. In another example embodiment 104a could be display panel and 104b could be an integrated display/touch panel. In another example embodiment 104a could be an integrated display/touch panel and 104b could be touch. Referring also to FIGS. 17-18, for the embodiment shown in FIG. 15, there could be one or more panels 104c located above the panels 104a, 104b, or below the panels 104a, 104b. For example, the panel(s) 104c could be a display panel(s), a touch panel(s) and/or an integrated display/touch panel(s).

With one example embodiment an apparatus 10 may be provided comprising a user interface panel 14 comprising a plurality of substrate layers 40 and a plurality of electrically conductive lines 42 on the substrate layers, where the substrate layers form perimeter side edges 38 of the user interface panel, where the electrically conductive lines 42 each have an end forming an electrical contact pad at the perimeter side edges, where the electrical contact pads 44 are arranged in rows at more than one of the perimeter side edges, and where each electrical contact pad is configured to directly connect to a separate contact 54 of a panel receiving socket 48.

The electrically conductive lines may comprise source lines and first gate lines which are generally perpendicular to each other. The electrically conductive lines may further comprise readout lines and second gate lines, where the user interface panel is a touch screen. The contact pads of the source lines, first gate lines, readout lines and second gate lines may be located at four respective ones of the perimeter side edges. The ends of each of the electrically conductive lines extend out of the substrate layers at their respective perimeter side edges and substantially immediately terminate in the contact pads 44 at their respective perimeter side edges without traversing any substantial distance longways along the respective perimeter side edge. The substrate layers may form a first shelf at a first one of the perimeter side edges having a first height and a second shelf at a second one of the perimeter side edges having a second height, where a first row of the electrical contact pads 44 are on the first shelf at the first height, and where a second row of the electrical contact pads 44 are on the second shelf at the second height. The apparatus may further comprise the panel receiving socket 48 having the user interface panel connected thereto, where the contacts 54 of the socket each have a first end 60 directly contacting the pads and a second end 58 connected to a printed wiring board. The apparatus may further comprise a display driver 32 electrically connected to the contacts of the socket, where the display driver is spaced from the user interface panel and the socket. The apparatus may comprise housing members forming exterior sides of the apparatus, where at least one of the housing members 74 forms a housing of the socket with an aperture having the user interface panel 76 therein, where the housing of the socket directly supports the contacts 77 thereon. The user interface panel 76 may be a touch sensitive panel located above a display screen. The touch panel can also be used without the display screen.

With another example embodiment an apparatus 10 may be provided comprising a socket 48 comprising electrical contacts 54; a user interface panel 14 mounted in the socket, where the user interface panel comprises a plurality of electrically conductive lines 42 extending across the user interface panel, where each of the electrically conductive lines comprises an end forming an electrical contact pad 44, where the electrical contact pads 44 are arranged in rows along perimeter edges of the user interface panel, where the electrical contacts 54 of the socket directly connect to the electrical contact pads at the perimeter edges; and a display driver 32 connected to the electrical contacts of the socket 48, where the display driver is spaced from the user interface panel. The electrically conductive lines 42 may comprise source lines and first gate lines which are generally perpendicular to each other. The electrically conductive lines 42 may further comprise readout lines and second gate lines, where the user interface panel is a touch screen. The contact pads of the source lines, first gate lines, readout lines and second gate lines may be at four respective ones of the perimeter side edges. The ends of each of the electrically conductive lines may extend out of the substrate layers at their respective perimeter side edges and substantially immediately terminate in the contact pads 44 at their respective perimeter side edges without traversing any substantial distance longways along the respective perimeter side edge. The substrate layers may form a first shelf at a first one of the perimeter side edges having a first height and a second shelf at a second one of the perimeter side edges having a second height, where a first row of the electrical contact pads are on the first shelf at the first height, and where a second row of the electrical contact pads are on the second shelf at the second height. The apparatus may comprise means for minimizing a size of non-active display area of the user interface panel at the perimeter edges. The apparatus may comprise housing members forming exterior sides of the apparatus, where at least one of the housing members 74 forms a housing of the socket with an aperture having the user interface panel therein, where the housing of the socket directly supports the contacts thereon. The user interface panel may be a touch sensitive panel located above a display screen.

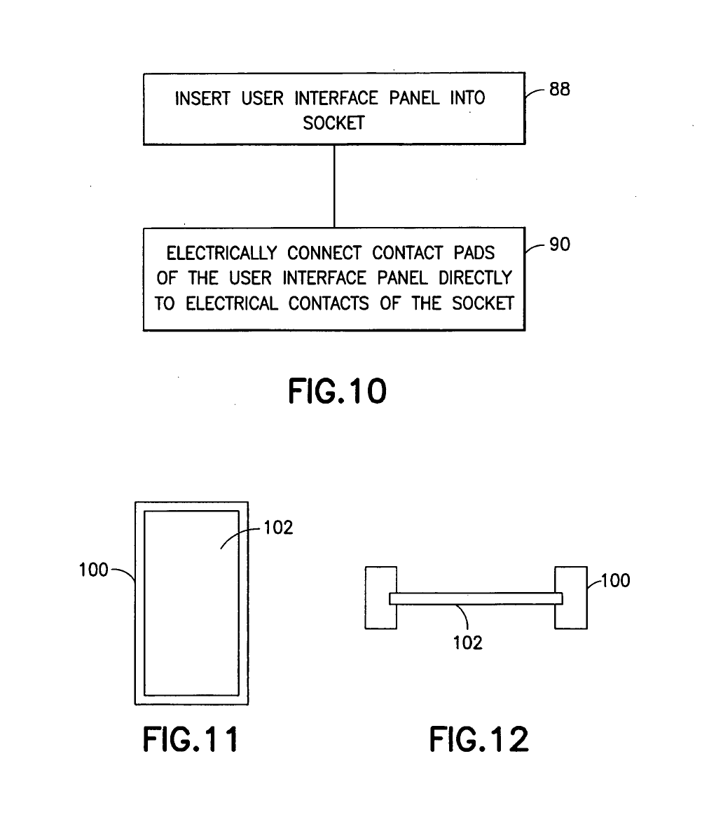

Referring also to FIG. 10, an example method may comprise inserting a user interface panel into a socket as indicated by block 88, where the user interface panel comprises a plurality of electrically conductive lines extending across the user interface panel, where each of the electrically conductive lines comprises an end forming an electrical contact pad, where the electrical contact pads are arranged in rows along perimeter edges of the user interface panel; and electrically connecting the contact pads directly to electrical contacts of the socket as indicated by block 90, where the electrical contact pads automatically directly contact the electrical contacts of the socket when the user interface panel is inserted into the socket.

It should be understood that the foregoing description is only illustrative. Various alternatives and modifications can be devised by those skilled in the art. For example, features recited in the various dependent claims could be combined with each other in any suitable combination(s). In addition, features from different embodiments described above could be selectively combined into a new embodiment. Accordingly, the description is intended to embrace all such alternatives, modifications and variances which fall within the scope of the appended claims.

What is claimed is:

1. An apparatus comprising a user interface panel comprising a plurality of substrate layers and a plurality of electrically conductive lines on the substrate layers, where the substrate layers form perimeter side edges of the user interface panel, where the electrically conductive lines each have an end forming an electrical contact pad at the perimeter side edges, where the electrical contact pads are arranged at more than one of the perimeter side edges, and where each electrical contact pad is configured to directly connect to a separate contact of a panel receiving socket.

2. An apparatus as in claim 1 where the electrically conductive lines comprise source lines and first gate lines which are generally perpendicular to each other.

3. An apparatus as in claim 2 where the electrically conductive lines further comprise readout lines and second gate lines, where the user interface panel is a display/touch panel.

4. An apparatus as in claim 3 where the contact pads of the source lines, first gate lines, readout lines and second gate lines are at at least two respective ones of the perimeter side edges.

5. An apparatus as in claim 1 where the ends of each of the electrically conductive lines extend out of the substrate layers at their respective perimeter side edges and substantially immediately terminate in the contact pads at their respective perimeter side edges without traversing any substantial distance longways along the respective perimeter side edge.

6. An apparatus as in claim 1 where the substrate layers form a first shelf having a first height and a second shelf having a second height, where a first row of the electrical contact pads are on the first shelf at the first height, and where a second row of the electrical contact pads are on the second shelf at the second height.

7. An apparatus as in claim 1 further comprising the user interface panel having the panel receiving socket connected thereto, where the contacts of the socket each have a first end directly contacting the pads and a second end connected to a printed wiring board.

8. An apparatus as in claim 7 further comprising a display driver electrically connected to the contacts of the socket, where the display driver is spaced from the user interface panel and the socket.

9. An apparatus as in claim 8 where the apparatus comprises housing members forming exterior sides of the apparatus, where at least one of the housing members forms a housing of the socket with an aperture having the user interface panel therein, where the housing of the socket directly supports the contacts thereon.

10. An apparatus as in claim 1 further comprising the user interface panel having the panel receiving socket connected thereto, where the user interface panel comprises multiple user interface panels.

11. An apparatus comprising:
a socket comprising electrical contacts;
a user interface panel mounted in the socket, where the user interface panel comprises a plurality of electrically conductive lines extending across the user interface panel, where each of the electrically conductive lines comprises an end forming an electrical contact pad, where the electrical contact pads are arranged along perimeter edges of the user interface panel, where the electrical contacts of the socket directly connect to the electrical contact pads at the perimeter edges; and
a display driver connected to the electrical contacts of the socket, where the display driver is spaced from the user interface panel.

12. An apparatus as in claim 11 where the electrically conductive lines comprise source lines and first gate lines which are generally perpendicular to each other.

13. An apparatus as in claim 12 where the electrically conductive lines further comprise readout lines and second gate lines, where the user interface panel is a touch screen.

14. An apparatus as in claim 13 where the contact pads of the source lines, first gate lines, readout lines and second gate lines are at at least two respective ones of the perimeter side edges.

15. An apparatus as in claim 11 where the ends of each of the electrically conductive lines extend out of the substrate layers at their respective perimeter side edges and substantially immediately terminate in the contact pads at their respective perimeter side edges without traversing any substantial distance longways along the respective perimeter side edge.

16. An apparatus as in claim 11 where the substrate layers form a first shelf having a first height and a second shelf having a second height, where a first row of the electrical contact pads are on the first shelf at the first height, and where a second row of the electrical contact pads are on the second shelf at the second height.

17. An apparatus as in claim 11 comprising means for minimizing a size of non-active display area of the user interface panel at the perimeter edges.

18. An apparatus as in claim 11 where the apparatus comprises housing members forming exterior sides of the apparatus, where at least one of the housing members forms a housing of the socket with an aperture having the user interface panel therein, where the housing of the socket directly supports the contacts thereon.

19. An apparatus as in claim 11 where the user interface panel comprises multiple user interface panels mounted to the socket.

20. A method comprising:
inserting a user interface panel into a socket, where the user interface panel comprises a plurality of electrically conductive lines extending across the user interface panel, where each of the electrically conductive lines comprises an end forming an electrical contact pad, where the electrical contact pads are arranged in rows along perimeter edges of the user interface panel; and
electrically connecting the contact pads directly to electrical contacts of the socket, where the electrical contact pads automatically directly contact the electrical contacts of the socket when the user interface panel is inserted into the socket.
